(19) United States
(12) Patent Application Publication
(10) Pub. No.: US 2001/0046716 A1
(43) Pub. Date: Nov. 29, 2001

(54) Method for manufacturing a semiconductor device

(76) Inventors: You-Sung Kim, Ichon-shi (KR); Min Huh, Ichon-shi (KR); Sung-Keun Chang, Ichon-shi (KR)

Correspondence Address: Finnegan, Henderson, Farabow,, Garrett & Dunner, L.L.P., 1300 I Street, N.W., Washington, DC, 20005-3315, US

(21) Appl. No.: 09/739,742

(22) Filed: Dec. 20, 2000

(30) Foreign Application Priority Data
Dec. 28, 1999 (KR) 1999-63572
Dec. 28, 1999 (KR) 1999-63573

(51) Int. Cl. H01L 21/00

(52) U.S. Cl. 438/3

(57) ABSTRACT

A method for manufacturing a semiconductor device includes the steps of: a) preparing an active matrix provided with at least one transistor, a plurality of conductive plugs electrically connected to the transistors and an insulating layer formed around the conductive plugs; b) forming a conductive layer on top of the active matrix; c) patterning the conductive layer a predetermined configuration, thereby obtaining a number of bottom electrodes; d) forming a first BST layer; and e) forming a second BST layer.

### FIELD OF THE INVENTION

The present invention relates to a semiconductor device; and, more particularly, to a semiconductor memory device incorporating a pair of high K dielectric layers therein as a capacitor dielectric film to improve a density quality of the capacitor dielectric as well as a step coverage thereof.

### DESCRIPTION OF THE PRIOR ART

As is well known, a dynamic random access memory (DRAM) with at least one memory cell comprised of a transistor and a capacitor has a higher degree of integration mainly by down-sizing through micronization. However, there is still a demand for downsizing the area of the memory cell.

To meet the demand, there have been proposed several structures for the capacitor, such as a trench type or a stack type capacitor, which are arranged three-dimensionally in a memory device to reduce the cell area available to the capacitor. However, the process of manufacturing three-dimensionally arranged capacitor is a long and tedious one and consequently involves high manufacturing cost. Therefore, there is a strong demand for a new memory device that can reduce the cell area with securing a requisite volume of information without requiring complex manufacturing steps.

In attempt to meet the demand, there have been introduced a high K dielectric, e.g., Ta₂O₅ or the like, as a capacitor thin film in place of conventional silicon oxide film or silicon nitride film. Since, however, a Ta₂O₅ layer is grown with a columnar structure during a following heat-treatment process, the grown Ta₂O₅ layer becomes a high leakage current. Therefore, it is very difficult for applying the Ta₂O₅ layer to a capacitor thin film for use in memory device.

Alternatively, a multi-layer dielectric, e.g., Ta₂O/TiO₂ or Ta₂O/Al₂O₃, has been proposed to use as a capacitor thin film by using a metal organic chemical deposition (MOCVD) to overcome the above-described problem. However, the MOCVD method makes a foreign material reside in the capacitor thin film. This result enforces the capacitor thin film to be performed a high temperature heat-treatment, which, in turn, generates a defect and a high leakage current in the capacitor thin film.

There are still demands for developing a high K dielectric having a low leakage current which is compatible with a semiconductor process.

### SUMMARY OF THE INVENTION

It is, therefore, an object of the present invention to provide a method for manufacturing a semiconductor device incorporating a pair of high K dielectric layers therein as a capacitor dielectric to improve a density quality of the capacitor dielectric as well as the step coverage thereof.

In accordance with one aspect of the present invention, there is provided a method for manufacturing a semiconductor device, the method comprising the steps of: a) preparing an active matrix provided with at least one transistor, a plurality of conductive plugs electrically connected to the transistors and an insulating layer formed around the conductive plugs; b) forming a conductive layer on top of the active matrix; c) patterning the conductive layer a predetermined configuration, thereby obtaining a number of bottom electrodes; d) forming a first BST layer; and e) forming a second BST layer.

### BRIEF DESCRIPTION OF THE DRAWINGS

The above and other objects and features of the present invention will become apparent from the following description of the preferred embodiments given in conjunction with the accompanying drawings, in which:

FIGS. 1A, 1B, 1C, 1D, 1E and 1F are schematic cross sectional views setting forth a method for the manufacture of the semiconductor memory device in accordance with the present invention.

### DETAILED DESCRIPTION OF THE PREFERRED EMBODIMENTS

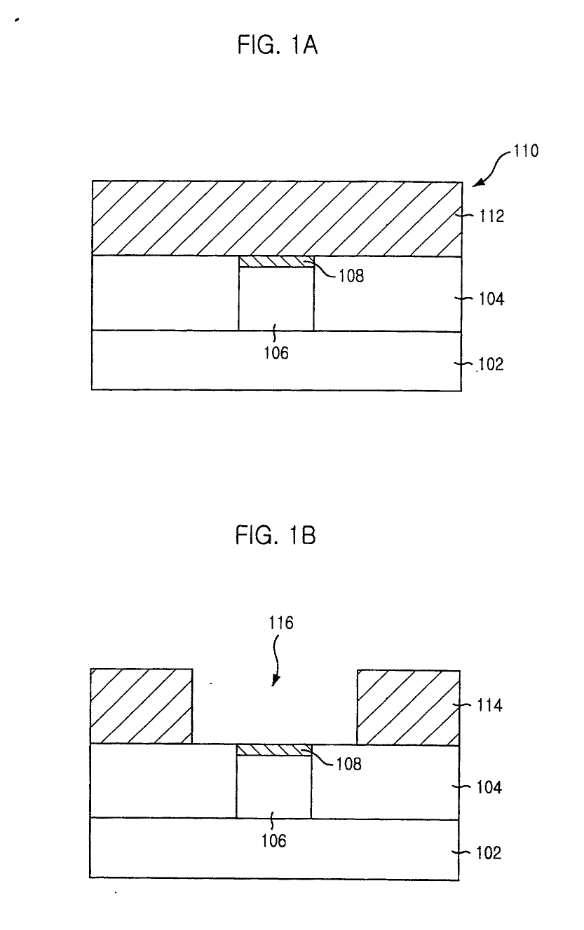

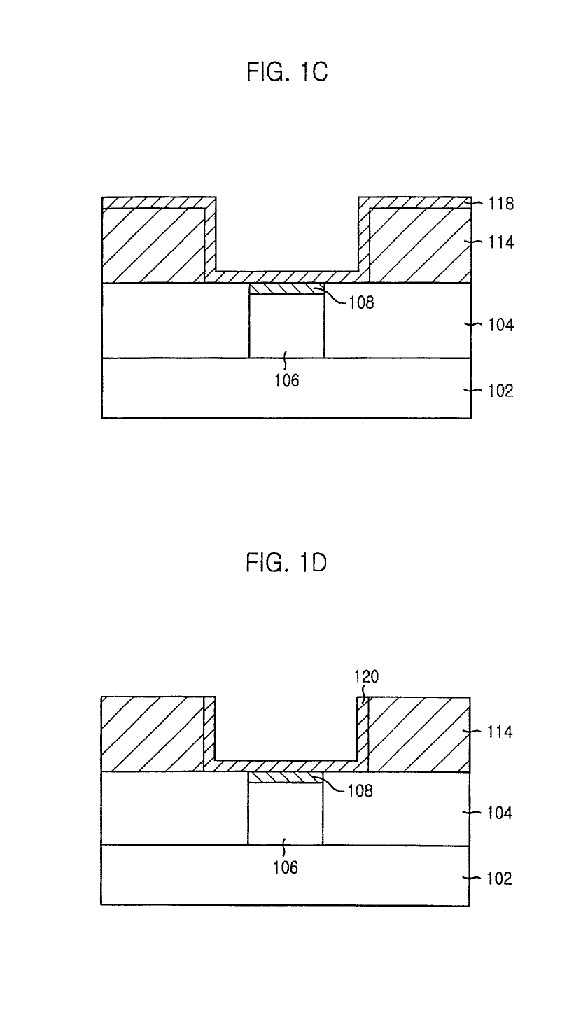

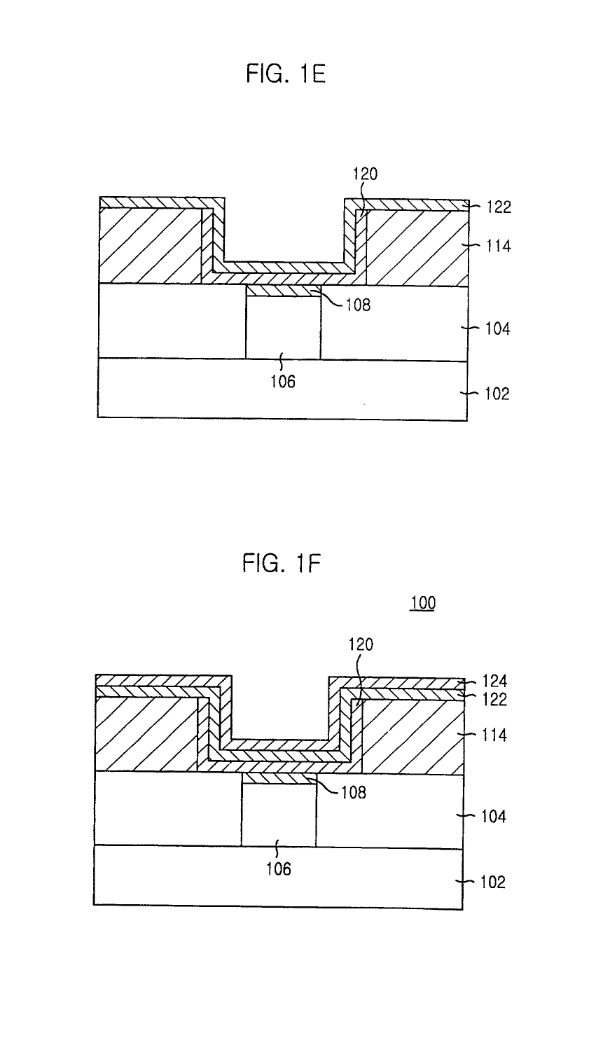

There are provided in FIGS. 1A to 1F a cross sectional view of a semiconductor device 100 for use in a memory cell and cross sectional views setting forth a method for the manufacture thereof in accordance with preferred embodiments of the present invention.

The process for manufacturing the semiconductor device begins with the preparation of an active matrix 110 including a silicon substrate 102, a contact plug 106, a diffusion barrier 108, a first inter-layer dielectric (ILD) 104 surrounding the contact plug 106 and the diffusion barrier 108 and a second ILD layer 114, as shown in FIG. 1A. The contact plug 106 is electrically connected to a diffusion region (not shown). It is preferable that the contact plug 106 is made of a material such as poly-silicon.

In a following step, the second ILD layer 114 is patterned into a predetermined configuration 116, thereby opening the diffusion barrier 108, as shown in FIG. 1B.

Thereafter, a first metal layer 118 is formed on the patterned first ILD layer 114, as shown in FIG. 1C. It is preferable that the first metal layer 118 is made of a material selected from a group consisting of Pt, Ru, Ir, RuO₂, IrO₂ and the like.

In an ensuing step, the first metal layer 118 is planarized by using a method such as a chemical mechanical polishing (CMP), thereby forming a lower electrode 120 on top of the diffusion barrier 108, as shown in FIG. 1D. In this step, the patterned second ILD layer 114 serves as an etching stop during the planarization process. It is preferable that the lower electrode 120 is in the form of cylinder.

Thereafter, a first BST layer 122 is formed on the lower electrodes 120 and the patterned second ILD layer 114 by using a physical vapor deposition (PVD). The first BST layer 122 has a thickness in the range of approximately 200 \acute{Å} to approximately 300 \acute{Å}. The PVD is carried out at a temperature ranging from approximately 400° C. to approximately 500° C. It is preferable that a composition ratio of Ba:Sr:Ti is equal to 0.5:0.5:1.

Next, a second BST layer 124 is formed on the first BST layer 122 by using a chemical vapor deposition (CVD), as shown in FIG. 1F. The second BST layer 124 has a thickness in the range of approximately 200 \acute{Å} to approximately 300 \acute{Å}. The CVD is carried out at a temperature in the range of 400° C.-500° C. and at a pressure in the range of 1-2 Torr. It is preferable that a composition ratio of Ba:Sr:Ti is equal to 0.5:0.5:1.

Thereafter, the first and the second BST layers 122, 124 are carried out an UV/O₃ process at a temperature ranging from approximately 400° C. to approximately 500° C. to remove inorganic material containing therein. The UV/O₃ process is carried out at a power range of approximately 125 mW/cm². It is preferable that a concentration of O₃ is approximately 25 mg/Nm. The UV/O₃ process is carried out for 5-20 minutes.

And then, the first and the second BST layer 122, 124 are carried out a heat treatment by using a rapid thermal process (RTP) at a temperature in the range of 600° C. to 1,000° C. to densify the first and the second BST layer 122, 124. Alternatively, the RTP is replaced with a furnace.

Thereafter, a second metal layer (not shown) is formed on the second BST layer 124 and patterned into the second metal layer, the first and the second BST layers 122, 124 into a memory block, thereby obtaining the semiconductor device 100. It is preferable that a material of the second metal layer is the same that of the first metal layer 118.

In comparison with the prior art, the present invention is capable of improving step coverage of the capacitor dielectric layer as well as a density quality thereof. This is achieved by forming the capacitor dielectric layer with two steps deposition. That is, the density quality is improved since the first step is carried out by using a PVD method. And, the second step is carried out by using a CVD method to improve the step coverage of the capacitor dielectric layer.

While the present invention has been described with respect to the particular embodiments, it will be apparent to those skilled in the art that various changes and modifications may be made without departing from the scope of the invention as defined in the following claims.

What is claimed is:

1. A method for manufacturing a semiconductor device, comprising the steps of:
a) preparing an active matrix having at least one transistor, a plurality of conductive plugs electrically connected to the transistors and an insulating layer adjacent the conductive plugs;
b) forming a conductive layer over the active matrix;
c) patterning the conductive layer into a predetermined configuration to obtain a plurality of bottom electrodes;
d) forming a first BST (Ba:Sr:Ti) layer over the patterned conductive layer; and
e) forming a second BST (Ba:Sr:Ti) layer over the first BST (Ba:Sr:Ti)

2. The method of claim 1, wherein the bottom electrode includes a material selected from a group consisting of Pt, Ru, Ir, RuO₂ and IrO₂.

3. The method of claim 1, the step of forming a first BST (Ba:Sr:Ti) layer includes physical vapor deposition (PVD).

4. The method of claim 3, wherein the first BST (Ba:Sr:Ti) layer has a thickness in the range of approximately 200 \acute{Å} to approximately 300 \acute{Å}.

5. The method of claim 3, wherein the physical vapor deposition (PVD) is carried out at a temperature ranging from approximately 400° C. to approximately 500° C.

6. The method of claim 1, wherein a composition ratio of BST (Ba:Sr:Ti) of the first BST (Ba:Sr:Ti) layer is equal to 0.5:0.5:1.

7. The method of claim 1, wherein the step of forming a second BST (Ba:Sr:Ti) includes chemical vapor deposition (CVD).

8. The method of claim 7, wherein the second BST (Ba:Sr:Ti) layer has a thickness in the range of approximately 200 \acute{Å} to approximately 300 \acute{Å}.

9. The method of claim 7, wherein the chemical vapor deposition (CVD) is carried out at a temperature in the range of 400° C.-500° C. and at a pressure in the range of 1-2 Torr.

10. The method of claim 1, wherein a composition ratio of BST (Ba:Sr:Ti) of the second BST (Ba:Sr:Ti) layer is equal to 0.5:0.5:1.

11. The method of claim 1, further comprising heat treatment by using an UV/O₃ process at a temperature ranging from approximately 400° C. to approximately 500° C. after forming the second BST (Ba:Sr:Ti) layer.

12. The method of claim 11, wherein the UV/O₃ process is carried out at a power range of approximately 125 mW/cm².

13. The method of claim 11, wherein a concentration of O₃ during the US/O₃ process is approximately 25 mg/Nm.

14. The method of claim 11, wherein the UV/O₃ process is carried out for 5-20 minutes.

15. The method of claim 11, further comprising heat treatment by using a furnace above 600° C. after the UV/O₃ process.

16. The method of claim 11, further comprising heat treatment by using a rapid thermal process (RTP) above 600° C. after the UV/O₃ process.
